(19) United States
(12) Patent Application Publication
(10) Pub. No.: US 2009/0074088 A1
(43) Pub. Date: Mar. 19, 2009

(54) Adaptive Fragmentation for HARQ in Wireless OFDMA Networks

(76) Inventors: Zhifeng Tao, Allston, MA (US); Anfei Li, Chicago, IL (US); Koon Hoo Teo, Lexington, MA (US); Jinyun Zhang, Cambridge, MA (US)

Correspondence Address: MITSUBISHI ELECTRIC RESEARCH LABORATORIES, INC., 201 BROADWAY, 8TH FLOOR, CAMBRIDGE, MA, 02139, US

(21) Appl. No.: 11/854,790

(22) Filed: Sep. 13, 2007

(51) Int. Cl. H04J 11/00; H03M 13/03; H04L 27/28

(52) U.S. Cl. 375/260; 370/343; 714/751; 714/E11.007

(57) ABSTRACT

A method performs a hybrid automatic repeat-request (HARQ) operation in a wireless orthogonal frequency division multiple access (OFDMA) network. A quality of a channel between a transmitter and a receiver is estimated as an error metric. A packet for the HARQ operation is fragmented adaptively at the transmitter according to the estimated error metric. The fragmentation is performed at the HARQ layer when the error metric is less than a predetermined threshold, otherwise the fragmentation is performed at the MAC layer.

### FIELD OF THE INVENTION

This invention relates generally to mobile wireless networks, and in particular to a system and method of adaptive fragmentation for hybrid automatic repeat request (HARQ) operations on wireless channels of OFDMA networks.

### BACKGROUND OF THE INVENTION

OFDM

Orthogonal frequency-division multiplexing (OFDM) is frequently used to reduce multi-path interference in a physical layer (PHY) of channels of wireless communication networks. OFDM is specified for a number of wireless communications standards, e.g., IEEE 802.11a/g and IEEE 802.16d/16e.

OFDMA

Based on the OFDM, orthogonal frequency division multiple access (OFDMA) has been developed. With OFDMA, a separate sets of orthogonal tones (frequencies) are allocated to multiple transceivers (users) so that these transceivers can engage in parallel communication. For example, the IEEE 802.16/16e standard has adopted OFDMA as the multiple channel access mechanism for non-line-of-sight (NLOS) communications in frequency bands below 11 GHz.

ARQ

Automatic repeat-request (ARQ) is a protocol widely used in data transmission for error control at the medium access control (MAC) layer. With ARQ, the transmitter sends a number of data packets specified by a window size. Then, the receiver waits for the corresponding acknowledgement messages from receiver. The messages indicate whether the packets are successfully received. A variety of acknowledgement strategies, including cumulative ACK, selective ACK and negative ACK, have been devised to improve the performance of ARQ protocol. Currently, there are three types of ARQ protocols, namely, Stop and Wait, Go-back-N, and Selective Repeat. Selective Repeat ARQ is specified as an optional feature for implementation in the IEEE 802.16e standard for the OFDM/OFDMA PHY.

The ARQ window size is the maximum number of unacknowledged packets at a given time, e.g., size ≦1024 in the IEEE 802.16e standard specification under the achievable PHY capacity specified for an IEEE 802.16e system. This setting can lead to considerable resource underutilization on relay link in mobile multihop relay networks wherein higher capacity is provisioned. Moreover, the resource underutilization in current ARQ protocol will further deteriorate in the next generation advanced IEEE 802.16 network (e.g., IEEE 802.16m), wherein an even higher transmission rate will be used.

HARQ

Hybrid automatic repeat-request (HARQ) operations can be used for faster error control in wireless networks. When a packet is passed from a higher MAC layer down to the HARQ layer, the transmitter uses coding technique to generate multiple copies of packet based upon the original packet. These multiple copies can be a duplicate of the original packet, or can include content derived based upon the original packet, such as parity bits. With HARQ, if the receiver detects an error in a packet, then the receiver signals the error to the transmitter. Then, the transmitter retransmits another copy of the original packet. The receiver can combine the information obtained from the multiple copies received and thus increase the probability of successfully decoding the packet.

The HARQ operation requires support at both the PHY and MAC layer, i.e., layer 1 and 2 in the OSI protocol model, to provide a desired reliability on the wireless link. Many existing wireless systems have adopted HARQ to deal with adverse wireless channels and improve reliability. For example, a multi-channel stop and wait protocol is used for HARQ in the IEEE 802.16e standard for the OFDMA PHY. Each HARQ channel is identified by an ARQ Channel ID (ACID).

Fragmentation

Fragmentation improves efficiency of resource utilization in a wireless network. For instance, suppose a wireless channel can transport N₀ bits per unit time, when the channel quality is good. When the quality of a wireless channel degrades due to fading or mobility, the channel can only support N₁ bits per unit time, which is smaller than N₀. Instead of waiting until the quality of the channel becomes good again, the transmitter can partition the N₀ bits into multiple smaller fragments. Each fragment is equal to or less than N₁ bits. Thus, the smaller fragments are more likely to be transported correctly over the channel in the unit time.

At the MAC layer, the fragmentation operation on a connection is negotiated when the connection (channel) between the base station and mobile station is initialized by the MAC service access point (SAP). With fragmentation enabled, a transmitter partitions each data unit into multiple fragments and transmits the fragments separately. At the receiver, the fragmented data units are reassembled to recover the original data unit. MAC layer fragmentation is optional in the IEEE 802.16e standard.

A packet is also fragmented when if its size is larger than 4800 bits at the physical layer. This is because the forward error correction (FEC) in the IEEE 802.16e standard only encodes a data block with maximal size of 4800 bits.

The current IEEE 802.16e standard determines the fragmentation statically, that is, only when the connection is initialized. However, this static fragmentation can result in a degradation of the system performance over channels with time-varying quality incurred by mobility or channel fading. This is a serious problem for the relay link of a multihop relay network, and for next generation advanced IEEE 802.16 networks (e.g., IEEE 802.16m), as high capacity is one of the requirements for such networks. In order to address this problem, new protocols are required.

For sake of clarify and brevity, some terminologies and acronyms are defined herein as follows.

Subscriber station (SS): generalized equipment set providing connectivity between subscriber equipment and a base station (BS).

Mobile station (MS): a station in mobile service intended to be used while in motion or during halts at unspecified points. An MS is always a subscriber station (SS) unless specifically expected otherwise in the standard.

Relay station (RS): a station that conforms to the IEEE Std 802.16j standard and whose functions are (1) to relay data and possibly control information between other stations, and (2) to execute processes that indirectly support mobile multihop relay.

Protocol data unit (PDU): a set of data specified in a protocol of a given layer and including protocol control information of that layer, and possibly user data of that layer.

Service data unit (SDU): the protocol data unit of a certain protocol layer that includes the service data unit coming from the higher layer and the protocol control information of that layer.

### SUMMARY OF THE INVENTION

The embodiments of the invention provide a method for adaptive fragmentation operations between stations of an orthogonal frequency division multiple access (OFDMA) wireless communication network.

The fragmentation operations are dynamically adapted depending on an error metric (EM) of a channel quality between stations. For example, as the quality of a channel decreases, the bit error rate increases (BER), and as the quality increases the BER decreases. The BER also affects the packet error rate (PER). The quality of a channel can also be expressed in terms of the inverse signal-to-noise ratio (ISNR), which is 1/SNR. A lower ISNR usually means a lower BER, and a higher ISNR a higher BER.

More specifically, fragmentation is performed at the MAC layer with respect to the length requirement of a HARQ forward error correction coding (FEC) block when the error metric is greater than a predefined threshold (TH). Thus, no fragmentation at the HARQ layer is needed. When the error metric is less than the threshold, fragmentation is performed at the HARQ layer, rather than at the MAC layer.

### BRIEF DESCRIPTION OF THE DRAWINGS

FIG. 1 is a block diagram of HARQ operation with HARQ layer fragmentation and without MAC layer fragmentation at a transmitter according to an embodiment of the invention;

FIG. 2 is a block diagram of HARQ operation with MAC layer fragmentation and without HARQ layer fragmentation at a transmitter according to an embodiment of the invention;

FIG. 3 is a flow chart of adaptive fragmentation operation according to an embodiment of the invention.

FIG. 4 is a flow chart of adaptive fragmentation operation according to another embodiment of the invention; and

FIG. 5 is a block diagram of adaptive fragmentation according to an embodiment of the invention.

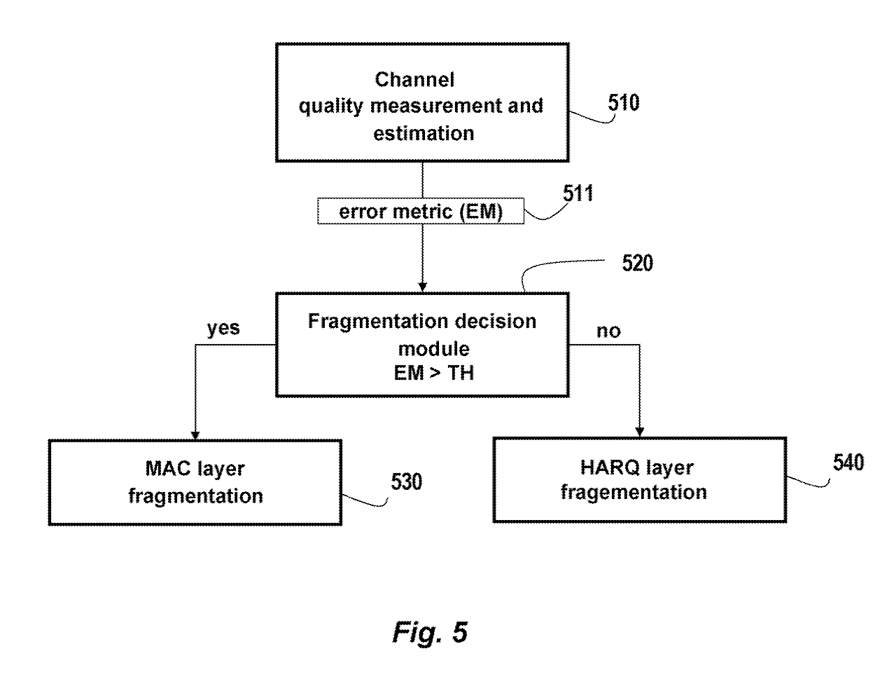

### DETAILED DESCRIPTION OF THE PREFERRED EMBODIMENTS

HARQ Operations without MAC Layer Fragmentation

Hybrid automatic repeat request (HARQ) is defined in the IEEE 802.16-2004 and 802.16e-2005 standards for the OFDMA physical (PHY) layer. The HARQ protocol, which requires both physical layer and MAC layer support, is a typical example of cross-layer system design for wireless communication networks. Combining MAC layer fragmentation and PHY/MAC cross-layer HARQ enables an integrated multi-layer control, which can improve system performance.

At the physical layer, two specific techniques, namely chase combining (CC) and incremental redundancy (IR), provide coding gain and additional redundancy gain for HARQ. In addition, a stop-and-wait mechanism is used by HARQ at the media access control (MAC) layer to provide automatic repeat request (ARQ) capability.

Because the technical specification related to HARQ in the IEEE 802.16-2004 standard has been modified in the IEEE 802.16e-2005 standard, the HARQ protocol defined in the IEEE 802.16e-2005 standard is used as a basis for further improvement and enhancement, as described herein.

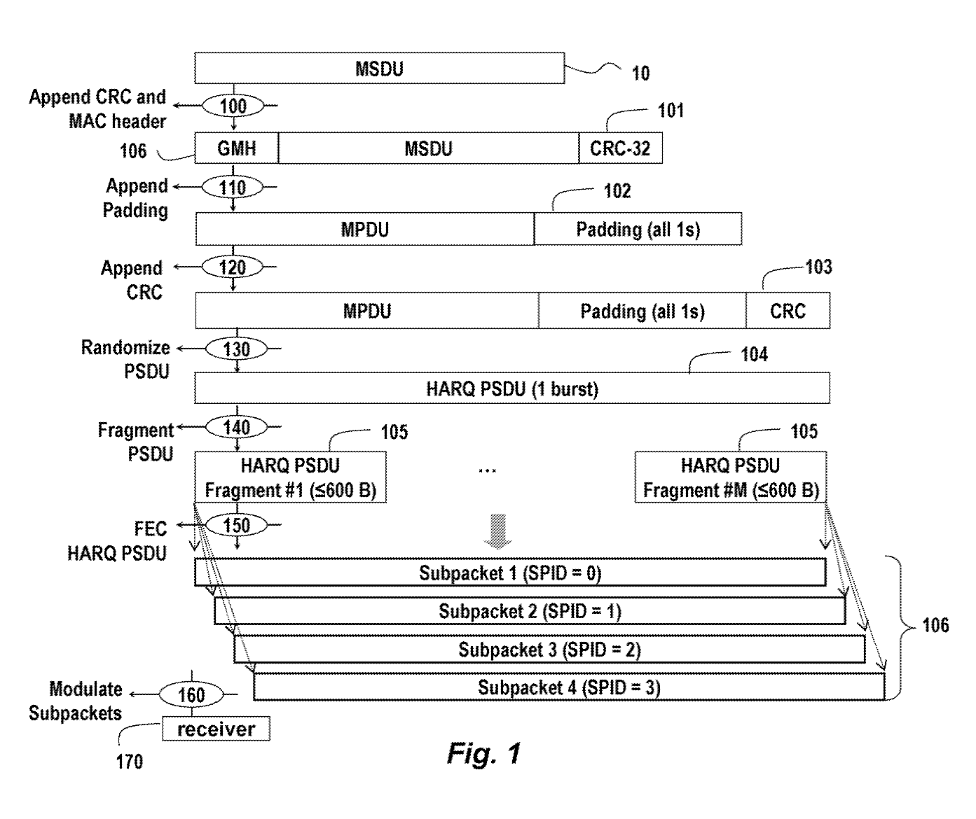

FIG. 1 shows the basic HARQ operation with MAC layer fragmentation disabled at a transmitter. A MAC SDU (MSDU) 10 or multiple MSDUs are passed down from the upper layer of the transmitter for the MAC operation. If packing is enabled, multiple MSDUs can be packed into one single MSDU, with packing subheader (PSH) being inserted in front of each individual MSDU along the packed sequence.

Then, a six-byte-long generic MAC header (GMH) 106 and an optional four-byte-long cyclic redundancy check (CRC-32) field 101 is attached 100 in the front and at the end of the MSDU or the packed MSDU sequence, respectively, to form a MAC PDU (MPDU). Multiple MPDUs can be further concatenated.

When the size of MAC PDU or concatenated MAC PDUs is not an element in the allowable set for HARQ, padding bits 102 are appended 110 at the end of MAC PDU or concatenated MAC PDUs. The amount of the padding is the same as the difference between the size of the PDU or concatenated MAC PDUs and the smallest element in the allowed set that is not less than the size of the PDU or concatenated MAC PDUs. The allowed set of resultant size is {4, 10, 16, 22, 34, 46, 58, 118, 238, 358, 598, 1198, 1798, 2398, 2998} bytes.

Then, a two-byte cyclic redundancy check (CRC-16) field 103 is appended 120. The permissible set of the resultant size then becomes {6, 12, 18, 24, 36, 48, 60, 120, 240, 360, 600, 1200, 1800, 2400, 3000} bytes. After randomization 130, the resultant HARQ physical layer SDU (PSDU) 104 has a length that is a multiple of 600 bytes, i.e., 4800 bits. Note that no additional bits are added in the randomization process 130.

If the total length of the HARQ PSDU is longer than 600 bytes, then the PSDU is fragmented 140 into fragments 105 no larger than 600 bytes each. Each fragment is encoded separately. The HARQ layer fragmentation operation is performed because the longest data unit that the forward error correction coding (FEC) 150 defined in the IEEE standard can handle is of 600 bytes.

Four subpackets 106 are generated for each HARQ PSDU, regardless of whether HARQ fragmentation occurs or not. The subpackets are modulated 160 and transmitted to receiver 170.

To simplify the following description, we call the HARQ PSDU 104, including the appended CRC field 103 and optional padding bits original encoder packet. Note that the four subpackets 106 are directly derived from the HARQ PSDU 104.

When the receiver fails to decode the first subpacket, then the receiver indicates a failure to the transmitter by sending a negative acknowledgement (NAK). In that case, the transmitter selects another subpacket out of the four subpackets 106 and transmits the selected subpacket to the receiver. This process continues until either the receiver decodes the original encoder packet correctly, or all four of such transmission attempts fail. This completes a HARQ operation for one HARQ PSDU.

If the ARQ protocol is operating above the HARQ, then it is up to the ARQ whether to retransmit the MAC PDU or concatenated MAC PDU.

HARQ Operations with MAC Layer Fragmentation

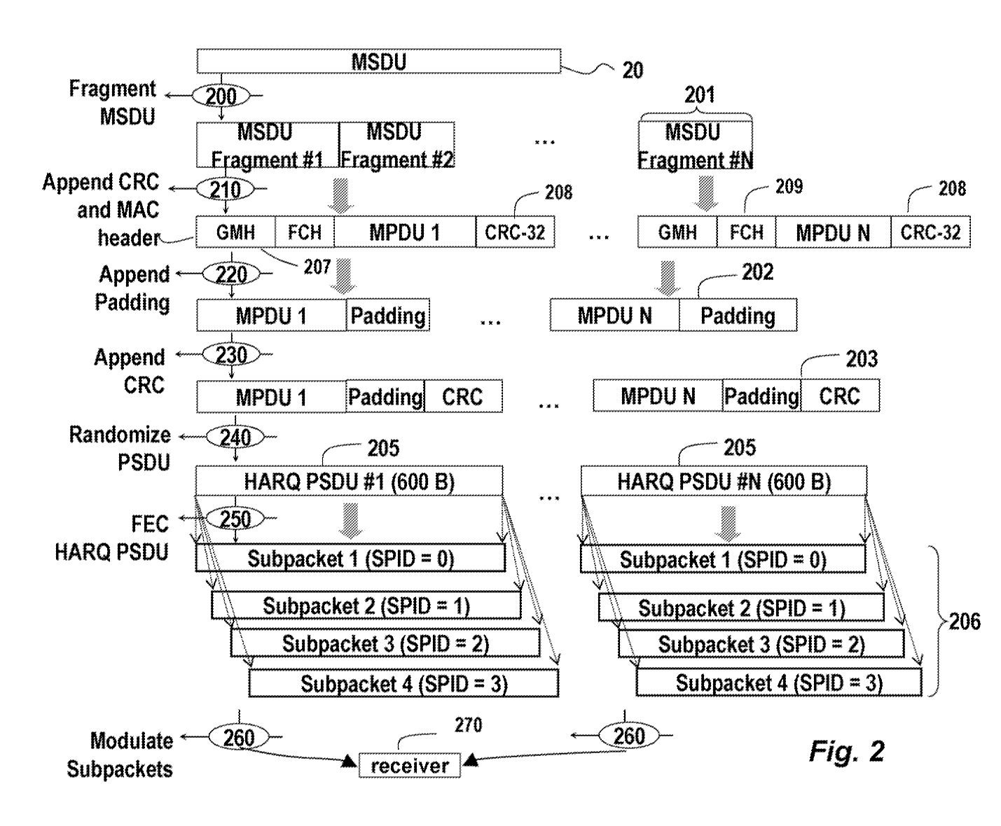

FIG. 2 shows the basic HARQ operations with MAC layer fragmentation at a transmitter. A single MAC SDU (MSDU) 20 or multiple MSDUs are passed down from the upper layer of the transmitter for the MAC operation. If packing is enabled, more than one MSDU can be packed into one MAC PDU. Packing subheaders (PSHs) needs to be inserted before MSDUs along the packed sequence.

The MSDU or the packed MSDUs are fragmented 200 into fragments 201 when the MSDU 20 or the packed MSDUs are longer than the fragmentation threshold L_{Frag}. The actual value of L_{Frag} is decided by the transmitter. Then, an MPDU is constructed by attaching 210 a six-byte GMH 207 and an optional four-byte cyclic redundancy check (CRC-32) field 208 in the beginning and at the end of the MSDU, respectively. If fragmentation is applied at the MAC layer, then fragmentation subheader (FCH) 209 has to be inserted before the MSDU fragment and after the GMH. Note that MSDU fragment and other MSDUs can be further packed into a single MPDU to improve the efficiency and wireless resource utilization. This is not explicitly shown in FIG. 2.

A single MAC PDU (MPDU) or a concatenation of multiple MPDUs is passed down for the HARQ operation. If needed, padding bits 202 are appended 220 at the end of the MPDU or concatenated MPDUs 201 so that the resultant MPDU or MPDU concatenation size is a value in the permissible set of {4, 10, 16, 22, 34, 46, 58, 118, 238, 358, 598} bytes. Then, a two-byte cyclic redundancy check (CRC-16) field 203 is appended 230. The total size of the resultant packet is in the permissible set {6, 12, 18, 24, 36, 48, 60, 120, 240, 360, 600} bytes.

After randomization 240, the resultant HARQ physical layer SDU (PSDU) 205 has a maximal length of 600 bytes, i.e., 4800 bits. Note that no extra bits are added during the randomization process. Four subpackets 206 are generated for each original encoder packet by the FEC 250. The subpackets are modulated 260 and transmitted to a receiver 270. The subpacket generated from different original encoder packet can be transmitted using different ACID.

Motivation for Adaptive Fragmentation for HARQ

In the current standard, fragmentation operations are only performed at the MAC layer, which is configured when a connection (channel) is initialized. Subsequently, the configuration remains static until the connection is terminated. This static configuration ignores the effect of fluctuating channel quality on the system throughput. This can lead to system performance degradation.

If the quality of a wireless channel is good when the connection is established, e.g., the bit error rate (BER) is as low as p₀, and the length of the MSDU is 1500 bytes, e.g., an Ethernet frame, then fragmentation at the HARQ layer is more efficient because of the relatively smaller overhead. If, due to mobility or channel fading, the BER of the assigned channel increases to p₁, the packet error rate (PER) also increases accordingly from 1−(1−p₀)^{L0} to 1−(1−p₁)^{L0} where L0 is the length of the packet. The excessive packet loss reduces system capacity significantly.

If MAC layer fragmentation is applied when the BER is p₁, and each fragment is of size L1, where L0>L1, then the packet error rate is reduced from 1−(1−p₁)^{L0} to 1−(1−p₁)^{L1}. That is, 1−(1−p₁)^{L1}<1−(1−p₁)^{L0}, where p₁>p₀, and L1>L0, This shows that an adaptive fragmentation is beneficial, when the quality of the channel is fluctuating.

To improve system performance, a dynamically estimated error metric (EM) of the channel quality can be taken into consideration when determining whether the fragmentation is performed at the MAC layer or at HARQ layer. Thus, an adaptive process is needed to achieve this goal. The channel quality is inversely proportional to the bit error rate (BER), the packet error rate (PER), and the ISNR.

Adaptive Fragmentation for HARQ

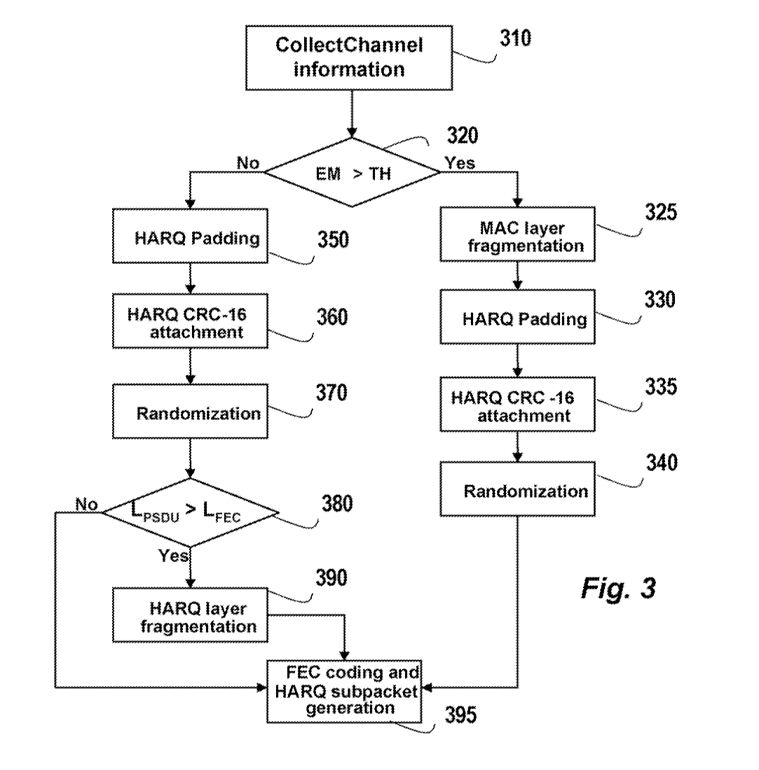

FIG. 3 shows the adaptive fragmentation process for HARQ according to an embodiment of the invention. In the transmitter, channel information is collected 310 and used to update the estimated error metric (EM) of the channel quality. The error metric (e.g., the bit error rate, packet error rate) is compared 320 to a threshold (TH). If the EM is greater than the threshold (TH), then the MAC layer fragmentation is applied 325 and the MSDU is fragmented, and each of the fragments is used to construct the MPDU. The size of MAC layer fragmentation complies with the length requirement of the HARQ FEC operation.

More specifically, suppose the maximum size of packet a HARQ FEC can handle at one time is L_{FEC} bytes. Assume the L_{FEC} is 600 bytes, which is the value specified in the current 802.16 standard. Then, the size of MAC layer fragment, which include generic MAC header, fragmentation subheader, the MSDU, and optional CRC-32, is in the set of {4, 10, 16, 22, 34, 46, 58, 118, 238, 358, 598}. If not, then HARQ padding bits are added 330 at the end of CRC-32. Note that padding bits may also be needed, since the MAC layer fragmentation is applied on the boundary of ARQ_BLOCK_SIZE, if MAC layer ARQ is in use. After that, a two-byte long CRC-16 is attached 335 at the end of the MPDU to make the size of the entire HARQ PSDU fall into the set {6, 12, 18,24, 36, 48, 60, 120, 240, 360, 600}. Therefore, no fragmentation is needed at the HARQ layer. Randomization 340 is performed, before the PSDU is coded and HARQ subpackets are generated 395.

If the EM is less than the threshold, then no fragmentation at MAC layer is required, and HARQ layer fragmentation is employed after the MPDU is generated and a HARQ PSDU is constructed using HARQ padding 350, CRC-16 attachment 360, and randomization 370. If the resultant HARQ PSDU has a length that is longer than L_{FEC} (e.g., 600) bytes in step 380, then the HARQ layer fragmentation 390 is required. Finally, FEC coding is applied and HARQ subpackets are generated 395.

The threshold (e.g., TH) is determined by comparing the performance of the two fragmentation mechanisms. The threshold is set to a value where a performance of the HARQ layer fragmentation and a performance of the MAC layer fragmentation are equal.

To further remove protocol overhead, the HARQ layer CRC-16 is not attached when the MAC layer CRC-32 is applied and no additional padding bits are appended. Basically, the same CRC-32 can be used by both HARQ and MAC layer error detection function. If padding bits have been added, then the bits that the CRC-32 protects are different from those that the CRC-16 protects, and thus both CRC-32 and CRC-16 are needed.

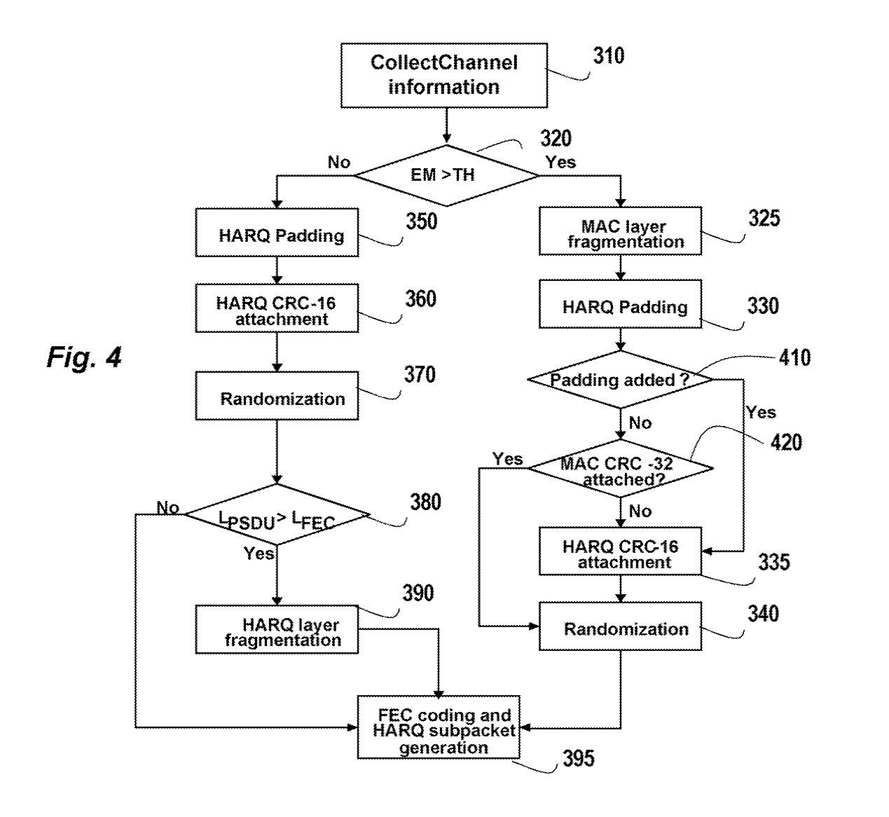

As shown in FIG. 4, the station collects 310 the channel information, and determines 320 if the EM is greater than the threshold. If true, the MAC layer fragmentation 325 is used. The size of MAC layer fragment, which includes generic MAC header, fragmentation subheader, the MSDU and proper padding 330 attached falls in the set of {4, 10, 16, 22, 34, 46, 58, 118, 238, 358, 598}, if no optional CRC-32 is attached.

If the optional CRC-32 is also present, otherwise, the size of MAC layer fragment is in the set of {6, 12, 18, 24, 36, 48, 60, 120, 240, 360, 600}, if no padding is needed. If the optional CRC-32 is present and paddings is needed to make the size of MAC layer fragment fall into the set of {6, 12, 18, 24, 36, 48, 60, 120, 240, 360, 600}, then the MAC layer fragment is padded 410 so that its size is in the set of {4, 10, 16, 22, 34, 46, 58, 118, 238, 358, 598}. If there are padding bits added in the MAC layer fragment, or there are no padding bits and no CRC-32 has been attached 420, then the two-byte long CRC-16 is attached at the very end of the MPDU in order to make the size of the entire HARQ PSDU fall into the set {6, 12, 18, 24, 36, 48, 60, 120, 240, 360, 600}. The resultant PSDU is randomized and coded for transmission. The remaining steps are as described for FIG. 3.

Implementation

We use the channel quality measurement and channel estimation function 510. As described above, a number of different error metrics (EM) 511 can be used, including but not limited to BER, PER, ISNR, and combinations thereof. We perform either the MAC layer fragmentation 530, or the HARQ layer fragmentation 540 as defined in the current IEEE 802.16 standard, based upon the decision 520 yielded by 520.

For the downlink transmission from, the BS to MS, the BS can make the decision 520 of whether fragmentation is performed at the MAC layer 530 or the HARQ layer 540 based on the error metric 511 of channel quality measurement and estimation 510.

For the uplink transmission from the MS to the BS, the MS can make the decision 520 of whether fragmentation is performed at the MAC layer 530 or the HARQ layer 540 based upon the channel information the MS gathers. As an alternative, the decision 520 can also be made at the BS, which then informs the MS of the decision.

The adaptive fragmentation method according to the embodiments of the invention is transparent to the receiver. Any receiver compliant with the current IEEE 802.16 standard supports this novel feature.

Although the invention has been described by way of examples of preferred embodiments, it is to be understood that various other adaptations and modifications may be made within the spirit and scope of the invention. Therefore, it is the object of the appended claims to cover all such variations and modifications as come within the true spirit and scope of the invention.

We claim:

1. A method for performing a hybrid automatic repeat-request (HARQ) operation in a wireless orthogonal frequency division multiple access network, comprising:
estimating dynamically an error metric of a channel between a transmitter and a receiver; and
fragmenting adaptively a packet for the HARQ operation at the transmitter according to the error metric estimated dynamically.

2. The method of claim 1, in which the fragmenting is performed at a HARQ layer of an open systems interconnection model when the error metric is less than a predetermined threshold.

3. The method of claim 1, in which the fragmenting is performed at a MAC layer of an open systems interconnection model when the error metric is greater than a predetermined threshold.

4. The method of claim 3, in which the fragmenting is only performed at the MAC layer.

5. The method of claim 1, further comprising:
signaling a capability to perform the adaptive fragmenting when the channel is initialized.

6. The method of claim 1, further comprising:
negotiating whether the fragmenting is performed when the channel is initialized.

7. The method of claim 1, in which the transmitter is a base station and the receiver is a mobile station.

8. The method of claim 1, in which the transmitter is a mobile station and the receiver is a base station.

9. The method of claim 1, in which the error metric is a bit error rate.

10. The method of claim 1, in which the error metric is a packet error rate.

11. The method of claim 1, in which the error metric is an inverse signal to noise ratio.

12. The method of claim 1, further comprising:
comparing a performance of fragmenting at a MAC layer and at a HARQ layer; and
setting the predetermined threshold to a value where the performances of the fragmenting at the MAC layer and the HARQ layer are equal.

13. A method for performing a hybrid automatic repeat-request (HARQ) operation in a wireless orthogonal frequency division multiple access network, comprising:
fragmenting a packet at a HARQ layer of an open systems interconnection model when an error metric of a channel between a transmitter and receiver is less than a predetermined threshold; and
fragmenting the packet at a MAC layer of the open systems interconnection model when the error metric is greater than the predetermined threshold.
